(19) United States
(12) Patent Application Publication
(10) Pub. No.: US 2006/0141712 A1
(43) Pub. Date: Jun. 29, 2006

(54) Method for manufacturing PMOSFET

(76) Inventor: Yun Seok Chun, Seoul (KR)

Correspondence Address: LADAS & PARRY LLP, 224 SOUTH MICHIGAN AVENUE, SUITE 1600, CHICAGO, IL, 60604, US

(21) Appl. No.: 11/123,556

(22) Filed: May 6, 2005

(30) Foreign Application Priority Data
Dec. 29, 2004 (KR) 10-2004-0114758

(51) Int. Cl. H01L 21/336

(52) U.S. Cl. 438/270; 438/589

(57) ABSTRACT

A method for manufacturing a PMOSFET uses a trench-type gate structure only in a PMOSFET region of a peripheral circuit, except for a cell, to overcome the shortcomings of a MOSFET caused by reduction in design rule, realize stable threshold voltage, and improve the characteristics and reliability of a PMOSFET transistor through reduction in channel dose.

### BACKGROUND OF THE INVENTION

1. Field of the Invention

The present invention relates to a method for manufacturing a PMOSFET, and more particularly to a method for manufacturing a PMOSFET using a trench-type gate structure only in a PMOSFET region of a peripheral circuit, except for a cell, to reduce the area of the peripheral circuit and improve the production yield rate.

2. Description of the Prior Art

As generally known in the art, a PMOSFET may be classified into a surface channel type and an embedded channel type. In the case of an embedded channel-type PMOSFET, the channel control becomes more difficult, as the device size decreases, due to degradation of threshold voltage and leak current characteristics, which are fundamental problems of the embedded channel.

A surface channel-type PMOSFET is difficult to be used in a memory device, because the fundamental problem of boron intrusion has not yet been solved. When a p-type gate is formed on a surface channel-type PMOSFET, in general, implantation is performed. In this case, boron intrudes into a channel of a silicon substrate in a following thermal process and results in threshold voltage shift and off-current increase. This deteriorates transistor characteristics.

An embedded channel-type transistor is generally used as the PMOS transistor of transistors in the peripheral region of a memory device. As the design rule becomes smaller, the short channel effect causes dropping of threshold voltage and increase in punch-through and leak current. This rapidly degrades the PMOS transistor characteristics.

In order to avoid such degradation in characteristics, a MPOSFET basically uses longer channels than an NMOSFET. This increases the overall size of a semiconductor chip and decreases the number of net dies.

### SUMMARY OF THE INVENTION

Accordingly, the present invention has been made to solve the above-mentioned problems occurring in the prior art, and an object of the present invention is to provide a method for manufacturing a PMOSFET using a trench-type gate structure only in a PMOSFET region of a peripheral circuit, except for a cell, to overcome the shortcomings of a MOSFET caused by reduction in design rule, realize stable threshold voltage, and improve the characteristics and reliability of a PMOSFET transistor through reduction in channel dose.

In order to accomplish this object, there is provided a method for manufacturing a PMOSFET including the steps of providing a semiconductor substrate having a PMOS region of a peripheral circuit defined thereon; forming an isolation layer in the substrate; forming a pad oxide film, a polycrystalline silicon film, and a first photoresist pattern for exposing a gate formation region successively on the substrate including the isolation layer; forming a hard mask by etching the polycrystalline silicon film using the first photoresist pattern as a mask; removing the first photoresist pattern; forming a trench by etching the pad oxide film and the substrate to a predetermined depth using the hard mask; removing the hard mask and the remaining pad oxide film successively; forming a screen oxide film on the surface of the substrate and the trench; performing As75 implantation for PMOS threshold voltage adjustment on the front surface of the resulting material; removing the screen oxide film; forming a gate oxide film and an undoped polycrystalline silicon film successively on the substrate and the trench; forming a P-type polycrystalline silicon film by implanting a P-type B11 in the resulting material; forming a tungsten silicide film, a nitride film, and a second photoresist pattern for exposing a gate formation region successively on the P-type polycrystalline silicon film; forming a hard mask by etching the nitride film using the second photoresist pattern; removing the second photoresist pattern; forming a P-type gate by etching the tungsten silicide film and the P-type polycrystalline silicon film using the hard mask; and forming a spacer on the lateral surface of the gate.

The pad oxide film is formed with a thickness of 50-100 Å and the polycrystalline silicon film is formed with a thickness of 1000-1500 Å in a chemical vapor deposition mode.

The trench is formed with a depth of 1000-2000Å.

The remaining pad oxide film is removed in a wet process using HF.

In the step of performing As75 implantation for PMOS threshold voltage adjustment, the As75 ions are supplied with dose of 1.0E12-1.5E13 and energy of 70-90 KeV.

The screen oxide film is removed using HF.

The gate oxide film is formed with a thickness of 25-60 Å in a wet oxidation process at a temperature of 750-900° C. in a furnace.

The undoped polycrystalline silicon film is continuously deposited with a thickness of 800-1500 Å at a temperature of 510-550° C.

In the step of performing P-type B11 implantation, the B11 ions are supplied with dose of 1.0E15-7.0E15 and energy of 3-10 KeV.

The tungsten silicide film is formed with a thickness of 800-1300Å.

### BRIEF DESCRIPTION OF THE DRAWINGS

The above and other objects, features and advantages of the present invention will be more apparent from the following detailed description taken in conjunction with the accompanying drawings, in which:

FIGS. 1A to 1I are sectional views showing processes of a method for manufacturing a PMOSFET according to the present invention.

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

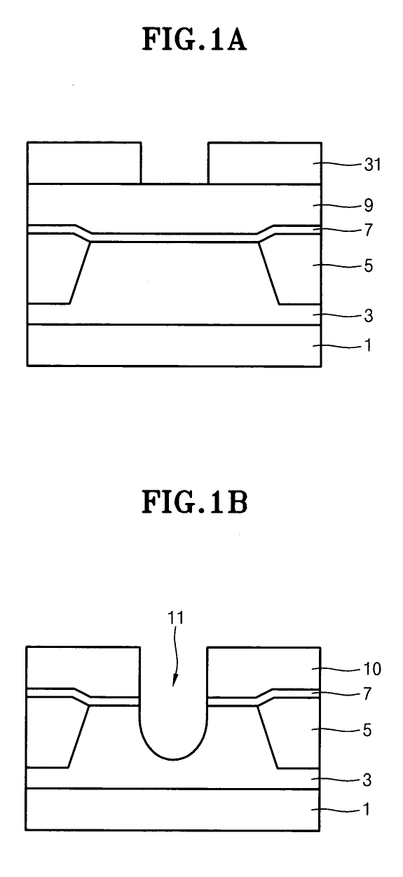

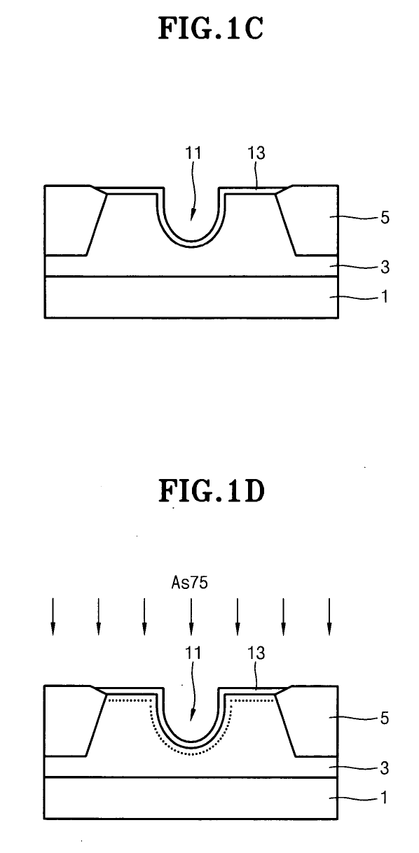

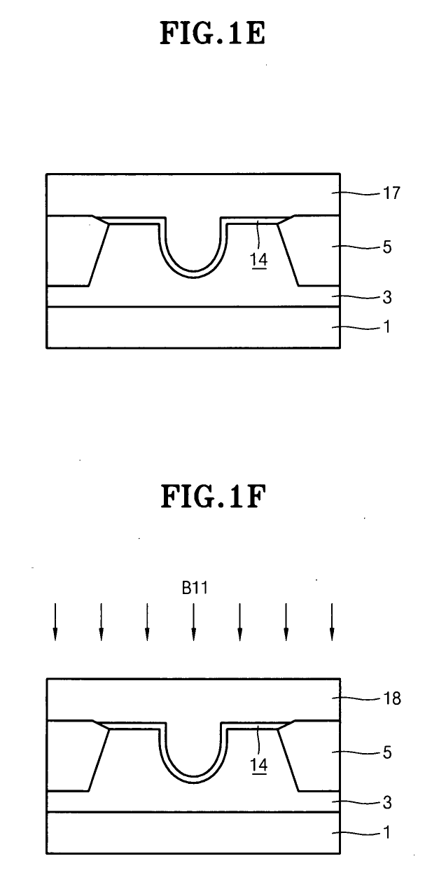

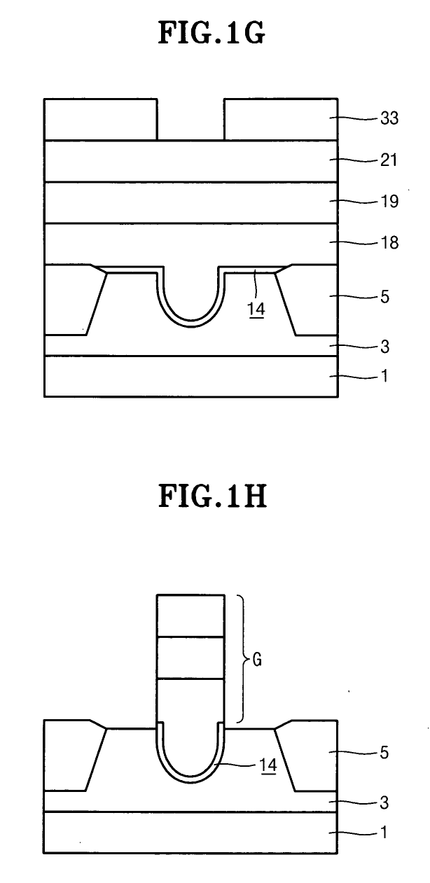

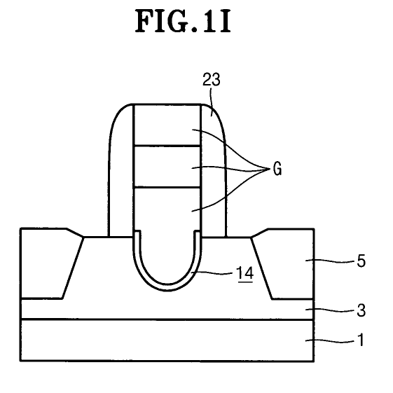

FIGS. 1A to 1I are sectional views showing processes of a method for manufacturing a PMOSFET according to the present invention.

In a method for manufacturing a PMOSFET according to the present invention, as shown in FIG. 1A, a semiconductor substrate 1 having a PMOS region of a peripheral circuit defined thereon is provided. An isolation layer 5 is formed on the substrate 1 in a conventional STI (shallow trench isolation) process and an N well 3 is formed thereon through implantation for well formation. A pad oxide film 7, a hard mask polycrystalline silicon film 9, and a first photoresist pattern 31 for exposing a gate formation region are successively formed on the substrate including the isolation layer 5. The pad oxide film 7 is formed with a thickness of 50-100 Å. The hard mask polycrystalline silicon film 9 is formed with a thickness of 1000-1500 Å in a chemical vapor deposition mode.

As shown in FIG. 1B, the first photoresist pattern is used as a mask to etch the hard mask polycrystalline silicon film and form a hard mask 10. The hard mask 10 is used to etch the pad oxide film and the substrate to a predetermined depth and form a trench 11 with a depth of 1000-2000 Å. The first photoresist pattern is then removed.

As shown in FIG. 1C, the hard mask and the remaining pad oxide film are successively removed. The remaining pad oxide film is removed in a wet process using HF. A screen oxide film 13 is then formed on the trench 11 and the substrate surface.

As shown in FIG. 1D, the front surface of the resulting material is subject to AS75 implantation for PMOS threshold voltage adjustment while supplying AS75 ions with dose of 1.0E12-1.5E13 and energy of 70-90 KeV.

In FIG. 1D, dashed lines refer to a region which has been subject to AS75 implantation for PMOS threshold voltage adjustment.

As shown in FIG. 1E, the screen oxide film is removed in a wet process using HF. A gate oxide film 14 and a undoped polycrystalline silicon film 17 are formed on the front surface of the substrate and the trench. The gate oxide film 14 is formed with a thickness of 25-60 Å in a wet oxidation process at a temperature of 750-900° C. in a furnace. The undoped polycrystalline silicon film 17 is continuously deposited with a thickness of 800-1500 Å at a temperature of 510-550° C.

As shown in FIG. 1F, the resulting material is subject to P-type B11 implantation to convert the polycrystalline silicon film into a P-type polycrystalline silicon film 18 while supplying B11 ions with dose of 1.0E15-7.0E15 and energy of 3-10 KeV.

As shown in FIG. 1G, a tungsten silicide film 19, a hard mask nitride film 21, and a second photoresist pattern 33 for exposing a gate formation region are successively formed on the P-type polycrystalline silicon film 18. The tungsten silicide film 19 is formed with a thickness of 800-1300Å.

As shown in FIG. 1H, the second photoresist pattern is used to etch the hard mask nitride film and form a hard mask (not shown). The second photoresist pattern is then removed. The hard mask is used to etch the tungsten silicide film and the P-type polycrystalline silicon film to form a P-type gate G.

As shown in FIG. 1I, a spacer 23 is formed on the lateral surface of the P-type gate G to complete the manufacturing of a PMOSFET.

According to the present invention, a trench is formed in a PMOS region of a peripheral circuit and a gate is formed on the trench. This substantially increases the two-dimensional effective channel length of the actual transistor, compared with a conventional transistor formed on a substrate, in the case of a PMOS transistor having the same planar size. As a result, the characteristics of the transistor improve.

In addition, decrease in drive current caused by three-dimensionally increased channel length is compensated for by using a surface channel-type PMOS. This secures low off-current characteristics and high on-current characteristics. Particularly, excellent BVDSS characteristics can be secured even at low threshold voltage. This improves on-current, realizes stable threshold voltage, and secures low off-current leak current characteristics.

As mentioned above, a trench is formed in a PMOS region of a peripheral circuit and a gate is formed on the trench according to the present invention. This substantially increases the effective channel length compared with a conventional PMOSFET. The leak current characteristics of the PMOS then improve. In addition, the present invention can form a PMOS having the same size as an NMOS and can secure a PMOS having a threshold voltage the leak current characteristics of which are excellent. This simplifies the circuit design, decreases the chip size, and increases the net dies.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A method for manufacturing a PMOSFET comprising the steps of:
providing a semiconductor substrate having a PMOS region of a peripheral circuit defined thereon;
forming an isolation layer in the substrate;
forming a pad oxide film, a polycrystalline silicon film, and a first photoresist pattern for exposing a gate formation region successively on the substrate including the isolation layer;
forming a hard mask by etching the polycrystalline silicon film using the first photoresist pattern as a mask;
removing the first photoresist pattern;
forming a trench by etching the pad oxide film and the substrate to a predetermined depth using the hard mask;
removing the hard mask and the remaining pad oxide film successively;
forming a screen oxide film on the surface of the substrate and the trench;
performing As75 implantation for PMOS threshold voltage adjustment on the front surface of the resulting material;
removing the screen oxide film;
forming a gate oxide film and an undoped polycrystalline silicon film successively on the substrate and the trench;
forming a P-type polycrystalline silicon film by implanting a P-type B11 in the resulting material;
forming a tungsten silicide film, a nitride film, and a second photoresist pattern for exposing a gate formation region successively on the P-type polycrystalline silicon film;
forming a hard mask by etching the nitride film using the second photoresist pattern;
removing the second photoresist pattern;
forming a P-type gate by etching the tungsten silicide film and the P-type polycrystalline silicon film using the hard mask; and
forming a spacer on the lateral surface of the gate.

2. The method for manufacturing a PMOSFET as claimed in claim 1, wherein the pad oxide film is formed with a thickness of 50-100Å.

3. The method for manufacturing a PMOSFET as claimed in claim 1, wherein the hard mask polycrystalline silicon film is formed with a thickness of 1000-1500 Å in a chemical vapor deposition mode.

4. The method for manufacturing a PMOSFET as claimed in claim 1, wherein the trench is formed with a depth of 1000-2000Å.

5. The method for manufacturing a PMOSFET as claimed in claim 1, wherein the remaining pad oxide film is removed in a wet process using HF.

6. The method for manufacturing a PMOSFET as claimed in claim 1, wherein, in the step of performing As75 implantation for PMOS threshold voltage adjustment, the As75 ions are supplied with dose of 1.0E12-1.5E13 and energy of 70-90 KeV.

7. The method for manufacturing a PMOSFET as claimed in claim 1, wherein the screen oxide film is removed using HF.

8. The method for manufacturing a PMOSFET as claimed in claim 1, wherein the gate oxide film is formed in a wet oxidation process at a temperature of 750-900° C. in a furnace.

9. The method for manufacturing a PMOSFET as claimed in claim 1, wherein the gate oxide film is formed with a thickness of 25-60Å.

10. The method for manufacturing a PMOSFET as claimed in claim 1, wherein the undoped polycrystalline silicon film is continuously deposited with a thickness of 800-1500 Å at a temperature of 510-550° C.

11. The method for manufacturing a PMOSFET as claimed in claim 1, wherein, in the step of performing P-type B11 implantation, the B11 ions are supplied with dose of 1.0E15-7.0E15 and energy of 3-10 KeV.

12. The method for manufacturing a PMOSFET as claimed in claim 1, wherein the tungsten silicide film is formed with a thickness of 800-1300Å.
